(19) United States
(12) Patent Application Publication
(10) Pub. No.: US 2015/0146389 A1
(43) Pub. Date: May 28, 2015

(54) DISPLAY DEVICE AND TELEVISION RECEIVER

(71) Applicant: SHARP KABUSHIKI KAISHA, Osaka-shi, Osaka (JP)

(72) Inventors: Tomohiro Okata, Osaka-shi (JP); Junichi Takeuchi, Osaka-shi (JP)

(73) Assignee: SHARP KABUSHIKI KAISHA, Osaka-shi, Osaka (JP)

(21) Appl. No.: 14/399,457

(22) PCT Filed: Mar. 14, 2013
(86) PCT No.: PCT/JP2013/057131

§ 371 Date: Nov. 6, 2014

(30) Foreign Application Priority Data
May 18, 2012 (JP) 2012-114655
Mar. 8, 2013 (JP) 2013-046441

(51) Int. Cl. H05K 7/02

(52) U.S. Cl. CPC H05K 7/02
USPC 361/752

(57) ABSTRACT

An attachment member of the stand support part is attached to a main unit of the television receiver. A connecting member is attached to the stand base part. The connecting member attached to the stand base part is inserted into a pole member of the stand support part attached to the main unit, and the connection between the pole member and the stand base part is fixed by setscrews.

### TECHNICAL FIELD

The present invention relates to a display device and a television receiver, in which a main unit is supported by a stand.

### BACKGROUND ART

A television receiver including a display device such as a liquid-crystal display, a plasma display or an organic electro luminescence (EL) display has widely been spread. A stationary television receiver is supported by a TV stand, provided at a television main unit, in a state where a display screen is standing. The television receiver has increased its weight as the display device becomes larger. In order to prevent the television receiver from falling or not to deteriorate the design of a stand, various devises have been made to the stand.

FIG. 1 is a perspective view of a television receiver. FIG. 1 illustrates the television receiver, in which a stand 8 attached to a surface (rear surface) opposite to a display screen supports a main unit 80, viewed from the rear side.

FIGS. 2A and 2B are schematic views illustrating the assembly procedure of the conventional stand 8. The stand 8 is constituted by a stand support part 81 and a stand base part 83. FIG. 2A illustrates a state where the stand support part 81 and the stand base part 83 are separated from each other, and FIG. 2B illustrates, in an enlarged view, a state where the stand support part 81 is being attached to the stand base part 83 with setscrews 84.

In order to reduce the packing volume when the television receiver is delivered, the main unit 80 and the stand 8 are often separated from each other at the time of delivery and, moreover, the stand support part 81 and the stand base part 83 are often separated from each other as shown in FIG. 2A. In such a case, for example, a purchaser or deliverer (delivery person) works to attach the stand 8 to the main unit 80 at the purchaser's home. The purchaser or deliverer takes out the main unit 80, stand support part 81 and stand base part 83 from a packing box, and first attaches the stand support part 81 to the main unit 80 as shown in FIG. 2A.

The stand support part 81 has an attachment member 81a of a substantially H shape and a pole member 81b of a cylindrical shape, one end of the pole member 81b being connected to the middle of the attachment member 81a. The stand support part 81 is connected to the main unit 80 by attaching the attachment member 81a to the rear surface of the main unit 80 with six setscrews 82. When the stand support part 81 is connected to the main unit 80, the other end of the pole member 81b protrudes a little in the short direction of the main unit 80 at the middle of one long side of the main unit 80. At an opening end of the other end of the pole member 81b, four bosses 81c are provided so as to bulge inward at four positions on the inner circumferential surface. Each boss 81c is provided with a screw hole extending in the axial direction of the pole member 81b.

The stand base part 83 is formed to have a shape of a rectangular frame, with a projection part 83b projecting inward at the middle part on one long side. The projection part 83b is provided with four through holes 83a so as to correspond, respectively, to the screw holes in the bosses 81c of the pole member 81b. When the stand base part 83 is attached to the stand support part 81, four setscrews 84 are put into the through holes 83a from the lower surface side of the stand base part 83 and are screwed and fitted to the screw holes of the bosses 81c of the pole member 81b.

Meanwhile, Patent Document 1 proposes a structure in which a stand attachment part is provided for temporarily fixing a stand to a display unit (main unit) while holding the stand at a predetermined posture and the stand is temporarily fixed to the display unit before being permanently fixed thereto with setscrews. With the use of the technique disclosed in Patent Document 1, the stand can easily or safely be attached to the display unit.

### BACKGROUND ART DOCUMENT

### Patent Document

### [Patent Document 1]

Japanese Patent Application Laid-open No. 2011-27872

### DISCLOSURE OF THE INVENTION

### Problems to be Solved by the Invention

When the stand base part 83 is attached to the stand support part 81 with the setscrews 84 as described above, a user (purchaser, delivery person) needs to rotate the setscrews 84 while holding the pole member 81b and stand base part 83 in the state where the screw holes of the bosses 81c of the pole member 81b are aligned with the through holes 83a of the stand base part 83. In other words, it is necessary to hold with one hand the pole member 81b and the stand base part 83 while, with the other hand, inserting the setscrews 84 into the through holes 83a and the screw holes, and rotating the setscrews 84 with a driver, which causes difficulty in attachment. Furthermore, in the state where the pole member 81b and stand base part 83 are held with one hand, the user may possibly drop the pole member 81b and stand base part 83 by mistake. When the pole member 81b is dropped by mistake, it may break the main unit 80 to which the pole member 81b is attached.

Moreover, in the technique disclosed in Patent Document 1, the stand attachment part is provided at a rear cabinet of the display unit, causing a problem in that the shapes of the rear cabinet and stand need to be changed in design depending on the size of the display unit (liquid-crystal module). This is because the size and arrangement position of the stand attachment part need to be changed depending on the size of the liquid-crystal module so as to sufficiently support the display unit.

The present invention has been made with the aim of solving the above problems. An object of the present invention is to provide a display device and a television receiver capable of easily and safely assembling a support part (stand) without a design change in a rear cabinet and a stand depending on the size of a display unit.

### Means of Solving the Problems

A display device according to the present invention, comprising a main unit provided with a display panel, and a support part supporting the main unit in a state where the display panel is standing, is characterized in that the support part comprises: a cylindrical pole member so attached to the main unit as to have an axis being parallel to a display surface of the display panel; a support member supporting the main unit through the pole member; a connecting member having one end attached to the support member and another end inserted into an opening end of the pole member, to connect the pole member and the support member; and a fixing member fixing the connection between the pole member and the support member through the connecting member.

According to the present invention, in the support part supporting the main unit provided with the display panel, a cylindrical pole member attached to the main unit and the support member supporting the main unit through the pole member are connected through the connecting member. In a state where one end is attached to the support member, the connecting member connects the pole member and the support member by inserting the other end thereof into the opening end of the pole member. Since the pole member and support member are fixed by the fixing member while being connected through the connecting member, it is unnecessary for the user to hold the pole member and the support member when the connection between the pole member and the support member is fixed.

The display device according to the present invention is characterized in that the above-described other end of the connecting member has resilience to spread in a diameter direction of the pole member when inserted into the opening end of the pole member.

According to the present invention, the other end of the connecting member has resilience spreading in the diameter direction of the pole member when inserted into the opening end of the pole member, which can prevent the connecting member inserted to the opening end of the pole member from falling off. Therefore, the pole member and the support member are not separated when the pole member and the support member are fixed, and thus the connection between the pole member and the support member can more easily and safely be fixed.

The display device according to the present invention is characterized in that the connecting member has a base of a rectangular parallelepiped shape and a plurality of board parts extending from the base in the same direction with predetermined intervals, and the board parts on both ends have protrusions at outer surfaces, the distance between the respective protruding ends of the protrusions being longer than an inner diameter of the pole member.

According to the present invention, the connecting member is constituted by a base of a rectangular-parallelepiped shape and a plurality of board parts extending in the same direction from the base with predetermined intervals. The protrusions formed on the outer side surfaces of the board parts on both ends are so configured as to have the distance between the respective protruding ends being longer than the inner diameter of the pole member. Accordingly, since the protrusions formed on the board parts of both ends press the inner circumferential surface of the pole member when the protruding ends of the plurality of board parts are inserted into the pole member, the connecting member can be prevented from falling off from the pole member. It is possible to form the protrusions integrally with the board parts and to easily form the connecting member having resilience spreading in the diameter direction of the pole member when inserted into the pole member.

The display device according to the present invention is characterized in that the board parts on the both ends have extending ends having outer side surfaces being formed as tapered surfaces.

According to the present invention, in the connecting member, the above-described other end to be inserted into the opening end of the pole member is formed to be tapering at the tapered surface, which makes it easier to insert the connecting member into the opening end of the pole member.

The display device according to the present invention is characterized in that the opening end of the pole member is provided with a guide part guiding the other end of the connecting member such that the other end is inserted at a predetermined position in a rotation direction centered on the axis of the pole member, and the other end of the connecting member is inserted into the opening end of the pole member in accordance with the guide part.

According to the present invention, the other end of the connecting member is inserted into the pole member at a predetermined position in the rotation direction centered on the axis of the pole member, which can prevent the other end of the connecting member from being inserted into the pole member at an incorrect position in the rotation direction centered on the axis. Therefore, the pole member and the connecting member can reliably be connected at an appropriate position in the rotation direction centered on the axis of the pole member. That is, it is possible to direct the orientation of the display panel, provided at the main unit to which the pole member is attached, to a predetermined direction with respect to the support member to which one end of the connecting member is attached.

The display device according to the preset invention is characterized in that the support member has a hole at an appropriate position, and one end of the connecting member has a protrusion to be fitted into the hole of the support member at a predetermined position in a rotation direction centered on the axis of the pole member into which the other end is inserted.

According to the present invention, a hole is opened at an appropriate position of the support member, and a protrusion which can be fitted into the hole is formed at one end of the connecting member. By fitting the protrusion at one end of the connecting member into the hole at the support member, the connecting member can be attached to the support member at a predetermined position in the rotation direction centered on the axis of the pole member. Since the support member and the connecting member can thus be connected at an appropriate position in the rotation direction centered on the axis of the pole member, the orientation of the display panel provided at the main unit to which the pole member is attached can be directed to a predetermined direction with respect to the support member.

The display device according to the present invention is characterized in that, the connecting member and/or the pole member are/is so configured, when the above-described other end of the connecting member is inserted into the opening end of the pole member, that the connecting member is not to be inserted further than a predetermined position in the axial direction of the pole member.

According to the present invention, when the other end of the connecting member is inserted into the opening end of the pole member, the connecting member is not inserted further than a predetermined position in the axial direction of the pole member. This can prevent the connecting member to be thrust into the pole member by mistake.

The display device according to the present invention is characterized in that the opening end of the pole member is provided with a cut-out part at an appropriate position, and one end of the connecting member is provided with a latch part to be engaged with the cut-out part, when the other end is inserted into the opening end of the pole member, to stop inserting of the connecting member.

According to the present invention, a cut-out part is formed at an appropriate position at the opening end of the pole member, and a latch part, engaging with the cut-out part to stop inserting of the connecting member when the other end of the connecting member is inserted into the opening end of the pole member, is formed at one end of the connecting member. This can reliably prevent the connecting member from being thrust into the pole member by mistake.

A display device according to the present invention, comprising a main unit provided with a display panel, and a support part supporting the main unit in a state where the display panel is standing, is characterized in that the main unit includes a recess having a circular cross section with its axial direction being the vertical direction, and that the support part comprises: a support member supporting the main unit; a connecting member having one end attached to the support member and another end inserted into the recess of the main unit, to connect the main unit and the support member; and a fixing member fixing the connection between the main unit and the support member through the connecting member.

According to the present invention, a recess having a circular cross section with the axial direction being the vertical direction is provided at the main unit provided with the display panel. The connecting member connects the main unit and the support member, while one end thereof being attached to the support member, by inserting the other end into the recess of the main unit. Since the main unit and the support member are fixed by a fixing member while being connected through the connecting member, it is unnecessary for the user to hold the main unit and the support member when the connection between the main unit and the support member is fixed.

The display device according to the present invention is characterized in that the support member and the connecting member are integrally molded.

According to the present invention, the support member and the connecting member are integrally molded, thereby eliminating the need for the work of attaching the connecting member to the support member, which can alleviate the burden of work of attaching the support part to the main unit.

A television receiver according to the present invention is characterized by comprising: any one of the above-described display devices; and a reception unit receiving a television broadcast, and in that an image is displayed on the display device based on the television broadcast received by the reception unit.

According to the present invention, a television receiver having a display device in which a support part can easily and safely be assembled can be realized, as described above.

### Effect of the Invention

According to the present invention, it is unnecessary for the user to hold a pole member and support member when the connection between the pole member and support member is fixed, so that the pole member can be fixed to the support member with both hands, which achieves easy, safe and reliable assembly of the support part. Moreover, a conventional housing (rear cabinet) having a display unit may be used, which eliminates the need for changing the design of the rear cabinet depending on the size of a display panel, allowing the same support part (stand) to be used in display devices with different sizes.

### BRIEF DESCRIPTION OF THE DRAWINGS

FIG. 1 is a perspective view of a television receiver;

FIG. 2A is a schematic view illustrating a procedure of assembly of a conventional stand;

FIG. 2B is a schematic view illustrating a procedure of assembly of a conventional stand;

FIG. 3A is a perspective view of a television receiver according to Embodiment 1;

FIG. 3B is a perspective view of a television receiver according to Embodiment 1;

FIG. 4 is a schematic view illustrating a structure of a stand;

FIG. 5A is a schematic view illustrating a procedure of connecting a stand base part and a connecting member;

FIG. 5B is a schematic view illustrating a procedure of connecting a stand base part and a connecting member;

FIG. 5C is a schematic view illustrating a procedure of connecting a stand base part and a connecting member;

FIG. 6A is an enlarged view of a connecting member;

FIG. 6B is an enlarged view of a connecting member;

FIG. 7A is a schematic view illustrating a procedure of connecting a pole member and a stand base part;

FIG. 7B is a schematic view illustrating a procedure of connecting a pole member and a stand base part;

FIG. 8 is a schematic view illustrating a procedure of connecting a pole member and a stand base part;

FIG. 9A is a schematic view illustrating a modification of the structure of a stand;

FIG. 9B is a schematic view illustrating a modification of the structure of a stand;

FIG. 10A is a schematic view illustrating a modification of the structure of a stand;

FIG. 10B is a schematic view illustrating a modification of the structure of a stand;

FIG. 10C is a schematic view illustrating a modification of the structure of a stand;

FIG. 11 is a schematic view illustrating a modification of the structure of a stand;

FIG. 12A is a perspective view of a television receiver according to Embodiment 2;

FIG. 12B is a perspective view of a television receiver according to Embodiment 2;

FIG. 13 is a schematic view illustrating the structure of a main unit and a stand according to Embodiment 2;

FIG. 14 is a schematic view illustrating the structure of a main unit and a stand according to Embodiment 2;

FIG. 15A is a schematic view illustrating a modification of the structure of a stand base part and a connecting member; and

FIG. 15B is a schematic view illustrating a modification of the structure of a stand base part and a connecting member.

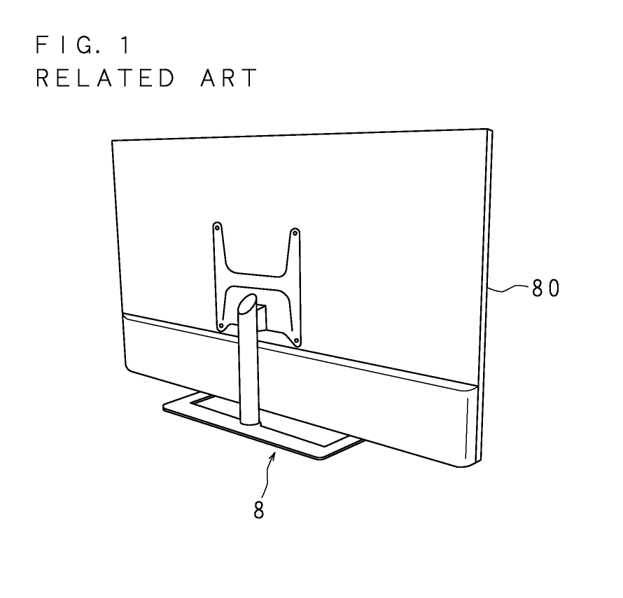

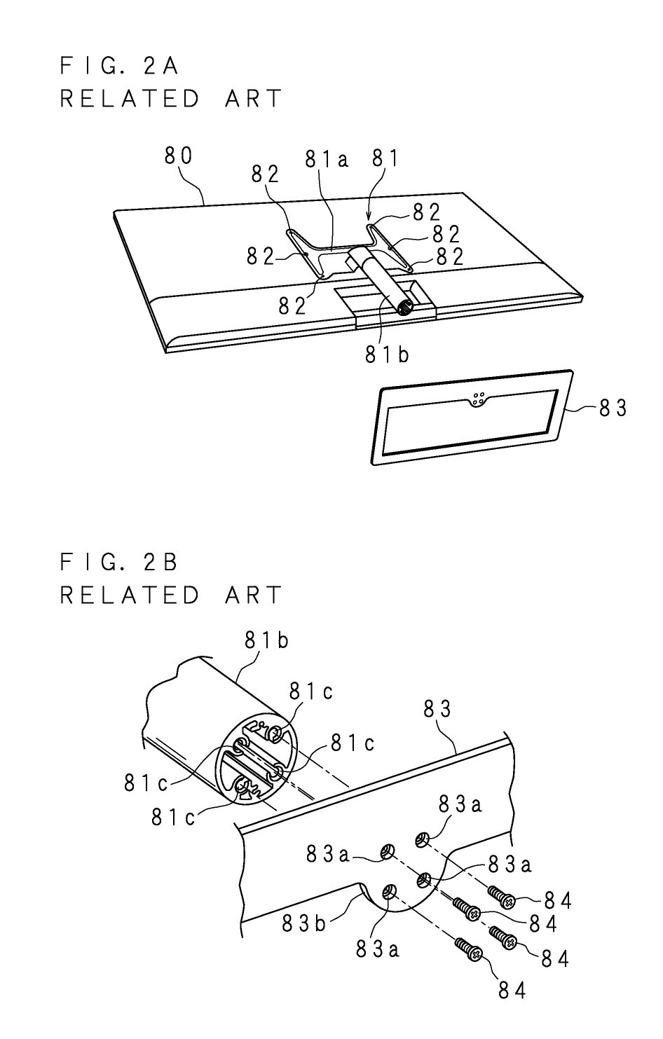

### MODE FOR CARRYING OUT THE INVENTION

The following will describe in detail the present invention with reference to the drawings illustrating some embodiments thereof.

### Embodiment 1

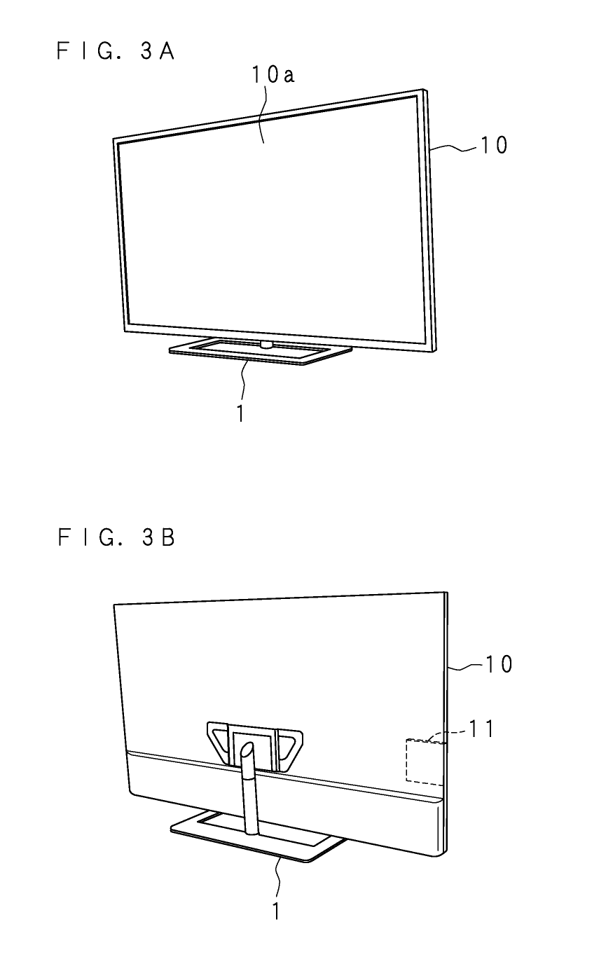

FIGS. 3A and 3B are perspective views of a television receiver according to Embodiment 1. FIG. 3A illustrates a state where the television receiver is viewed from the side of a display screen, whereas FIG. 3B illustrates a state where the television receiver is viewed from the side of a surface opposite to the display screen (hereinafter referred to as “rear surface”).

The television receiver according to Embodiment 1 is a display device including a rectangular main unit 10 provided with a display panel 10a such as a liquid-crystal panel, plasma panel or organic EL panel, and a stand (support part) 1 for supporting the main unit 10. The stand 1 supports the main unit 10 while the display panel 10a is standing. Moreover, the television receiver according to Embodiment 1 includes a reception unit 11 for receiving television broadcasts which is located inside the main unit 10, and displays an image on the display panel 10a based on the television broadcasts received at the reception unit 11.

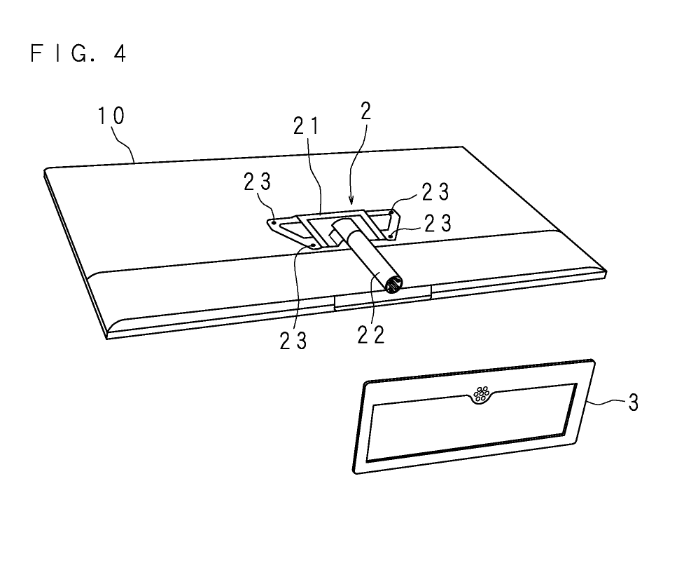

The structure and assembly procedure of the stand 1 according to Embodiment 1 will be described below. FIG. 4 is a schematic view illustrating the structure of the stand 1. The stand 1 has a stand support part 2 and a stand base part 3. FIG. 4 illustrates the state where the stand support part 2 is separated from the stand base part 3.

The stand support part 2 has an attachment member 21 of a substantially-rectangular plate shape and a pole member 22 of a cylindrical shape. One end of the pole member 22 is connected to the substantially middle of the attachment member 21, while the pole member 22 extends in the short direction of the attachment member 21, so as to form the stand support part 2 in a substantially T-shape.

The stand support part 2 is attached to the main unit 10 by attaching the attachment member 21 to the substantially middle of the rear surface (rear cabinet) of the main unit 10 with four setscrews 23. It is noted that the rear cabinet is provided with screw holes at a position to which the attachment member 21 is attached, and more specifically, positions to which the setscrews 23 are screwed and fitted, which can prevent the attachment member 21 from being attached to an incorrect position with respect to the main unit 10.

In the case where the stand support part 2 is attached to the main unit 10, the other end of the pole member 22 protrudes a little in the short direction of the main unit 10 at the middle of one long side of the main unit 10. Moreover, when the stand support part 2 is attached to the main unit 10, the axis of the pole member 22 is parallel to the rear surface of the main unit 10 and corresponds to the short direction of the main unit 10.

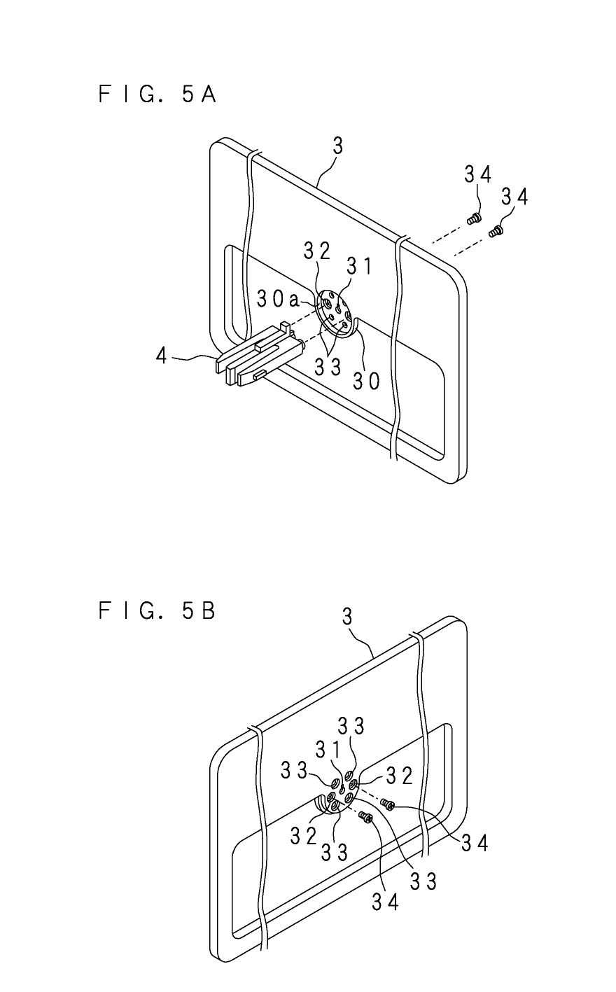

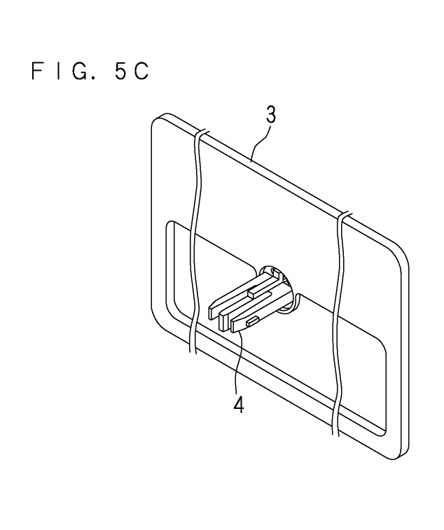

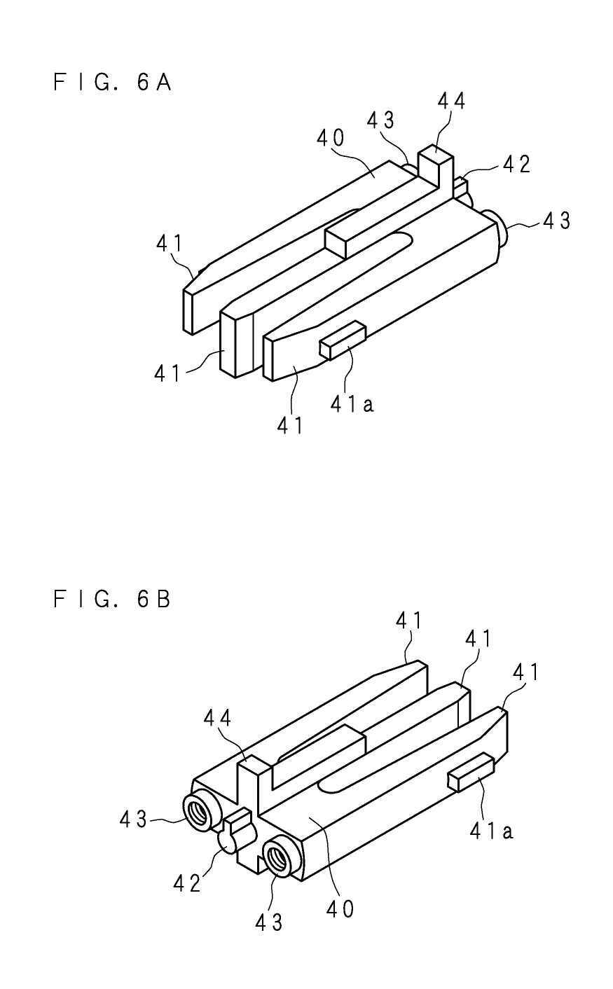

The stand 1 according to Embodiment 1 is formed by connecting the stand support part 2 and the stand base part 3 through a connecting member 4. FIGS. 5A, 5B and 5C are schematic views illustrating the procedure of connecting the stand base part 3 and the connecting member 4. FIGS. 5A and 5C illustrate the state where the stand base part 3 is viewed from the side to which the connecting member 4 is attached, whereas FIG. 5B illustrates the state where the stand base part 3 is viewed from a side (hereinafter referred to as “rear side”) opposite to the side to which the connecting member 4 is attached. Furthermore, FIGS. 6A and 6B are enlarged views of the connecting member 4.

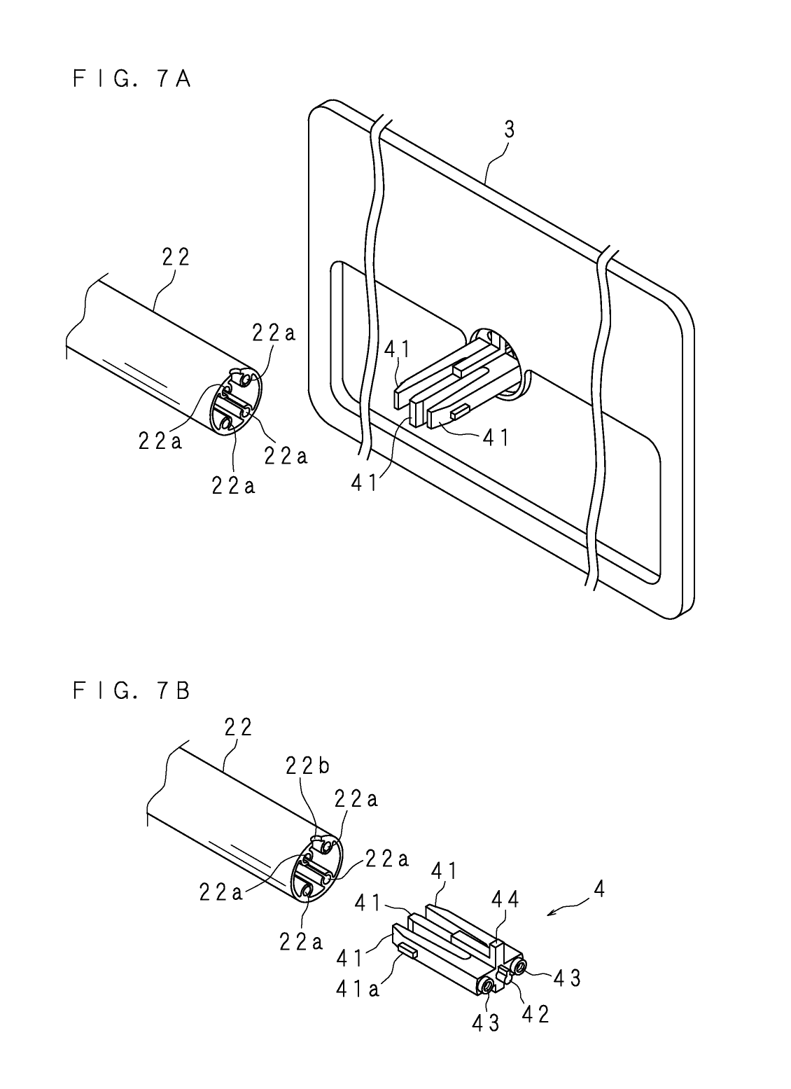

The connecting member 4 has one end attached to the stand base part 3 and the other end inserted into an opening end (the other end) of the pole member 22 as shown in FIGS. 7A and 7B, thereby connecting the pole member 22 and stand base part 3. The connecting member 4 is, for example, molded with synthetic resin, and has a base 40 of a rectangular block shape (rectangular parallelepiped shape) and three board parts 41 extending in the same direction from the base 40. The board parts 41 are aligned at equal intervals. The base 40 is provided with ribs at middle parts of the upper and lower surface thereof, respectively, so that the board part 41 in the middle is formed wider by the size of the rib than the board parts 41 on both ends (outer sides). Thus, as illustrated in FIG. 6B, the end surface of the base 40 is formed to have a substantially cross shape. Moreover, a protrusion 44 is formed on the base end side of the rib on the upper side of the base 40.

A tapered surface is formed on each of the outer side surfaces of the board parts 41 on both ends, such that the connecting member 4 tapers. On the outer side surfaces of the board parts 41 on both ends, protrusions 41a bulging outward are respectively formed near the ends where the tapered surfaces are formed. The two protrusions 41a are so formed that the distance between the respective protruding ends is a little longer than the inner diameter of the pole member 22.

On the end surface of the base 40 of the connecting member 4, a protrusion 42 is formed at a position corresponding to the middle board part 41 so as to extend in a direction opposite to the protruding direction of the board part 41. Protrusions 43 are also formed similarly at positions corresponding to the board parts 41 at both ends. The protrusion 42 is formed to have a cylindrical shape and is provided with a rib extending in the same direction as the protrusion 44 formed at the base 40, which makes the protrusion 42 have a cross section of a keyhole shape as a whole. Each of the two protrusions 43 is formed to have a cylindrical shape with a screw hole formed therein.

The stand base part 3 is formed to have a shape of a rectangular frame, one long side thereof being wider than the other long side, and a projection part 30 projecting inward is provided at the middle part on the widely-formed long side. At the projection part 30, a recess 30a having a circular cross section with a diameter which is approximately the same as the outer diameter of the pole member 22 is formed. At the recess 30a, through holes 31, 32 having cross sections large enough to receive the protrusions 42, 43, respectively, are formed at positions corresponding to the respective protrusions 42, 43 formed at the connecting member 4. The through hole 31 has a cross section of a keyhole shape as with the protrusion 42 of the connecting member 4, whereas each of the through holes 32 has a circular cross section as with each of the protrusions 43 of the connecting member 4. Moreover, the recess 30a is provided with four through holes 33 at positions corresponding to the respective screw holes of bosses 22a of the pole member 22, which will be described later.

The stand base part 3 is a support member for supporting the main unit 10 through the stand support part 2. The stand base part 3 is connected to the stand support part 2 (pole member 22) through the connecting member 4 to support the main unit 10, and thus is formed to have a weight and shape that allow the stand base part 3 to sufficiently support the main unit 10 so as to prevent the television receiver from falling. Moreover, the stand base part 3 is located at a position viewable by the user when the television receiver is placed thereon, and thus is formed to have a shape with a high regard for its design. Accordingly, the shape of the stand base part 3 is not limited to the shape of a rectangular frame as formed in Embodiment 1.

When the connecting member 4 with the configuration as described above is attached to the stand base part 3, in the state where the protrusions 42, 43 are fitted into the respective through holes 31, 32 formed at the recess 30a, setscrews 34 are put into the through holes 32 from the rear side of the stand base part 3 to be screwed and fitted into the screw holes of the protrusions 43. This allows the connecting member 4 to be fixed to the stand base part 3, as illustrated in FIG. 5C.

The through hole 31 of the stand base part 3 and the protrusion 42 of the connecting member 4 are formed to have a non-circular cross sections, which can prevent the connecting member 4 from being attached to the stand base part 3 with an incorrect orientation with respect to the stand base part 3. In addition, the two protrusions 43 are fitted into the through holes 32 of the stand base part 3 together with the protrusion 42 of the connecting member 4, so that the connecting member 4 can be attached to the stand base part 3 at a unique position in a rotation direction with the direction orthogonal to the stand base part 3 being the axis of rotation. It is, therefore, possible to prevent the connecting member 4 from being attached to the stand base part 3 with an incorrect position (orientation).

Furthermore, by forming the recess 30a at the stand base part 3 so as to urge the user to fit the connecting member 4 into the recess 30a, it is possible to prevent the connecting member 4 from being incorrectly attached to the stand base part 3 back to front. There may be a case where the stand base part 3 is constituted by a stand base main unit and a cover which covers the upper side of the stand base main unit. In such a case, without forming the recess 30a, the stand base main unit and the cover may be formed in different colors so as to urge the user to fit the connecting member 4 with the cover positioned on the upper side, thereby preventing the connecting member 4 from being incorrectly attached to the stand base part 3 back to front.

Furthermore, as the protrusions 43 of the connecting member 4 are fitted into the through holes 32 of the stand base part 3, the through holes 32 and the screw holes of the protrusions 43, through which the setscrews 34 pass, are aligned with each other, thereby allowing the setscrews 34 to be easily screwed and fitted.

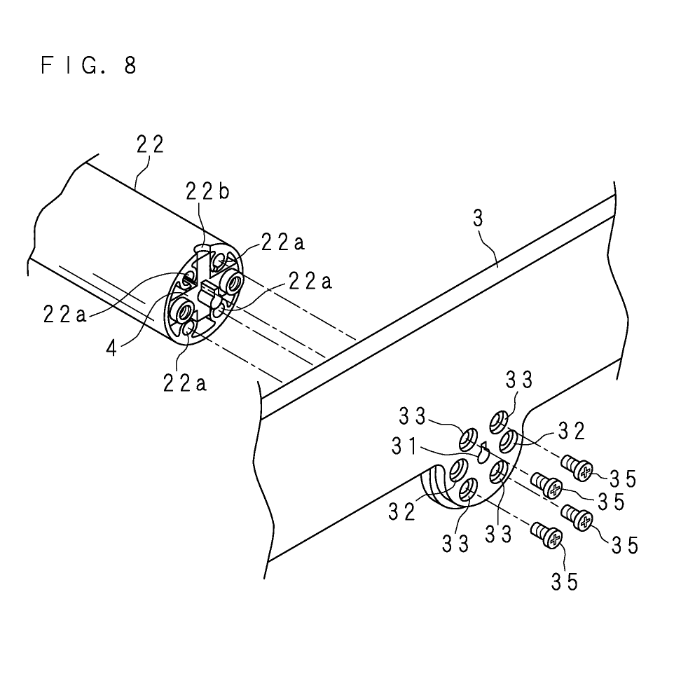

FIGS. 7A, 7B and 8 are schematic views illustrating the procedure of connecting the pole member 22 and the stand base part 3. While the connecting member 4 and the stand base part 3 are shown separately from each other in FIGS. 7B and 8, such that the state of inserting the connecting member 4 into the pole member 22 can easily be recognized, the connecting member 4 is, in practice, inserted into the pole member 22 while being attached to the stand base part 3.

Four bosses 22a are so provided as to bulge inward at four positions on the inner circumferential surface at the opening end of the other end (the end into which the connecting member 4 is inserted) of the pole member 22. At the bosses 22a, screw holes extending in the axial direction of the pole member 22 are opened. The bosses 22a are formed to have such an outer diameter as to allow the board parts 41 of the connecting member 4 to only be inserted at unique positions in the rotational direction centered on the axis of the pole member 22 when inserted from the opening end of the pole member 22, and to allow the inserted board parts 41 to be held between their outer circumferential surfaces. With such a structure, the bosses 22a function as guide parts which guide the inserting of the board parts 41 such that the connecting member 4 (board part 41) is inserted at a unique position in the rotational direction centered on the axis of the pole member 22. Accordingly, the board parts 41 of the connecting member 4 are inserted into the pole member 22 along the outer circumferential surfaces of the bosses 22a, thereby preventing the connecting member 4 from being inserted at an incorrect position with respect to the opening end of the pole member 22.

Meanwhile, the protrusions 41a formed on the board parts 41 at both ends of the connecting member 4 are so formed that the distance between the protruding ends of the protrusions 41a is a little longer than the inner diameter of the pole member 22. Therefore, when the board parts 41 are inserted into the pole member 22, a force is applied to the protrusions 41a of the connecting member 4 in a direction of making the two protrusions 41a come closer to each other. That is, such a force is applied to the tip side (protruding end side) of the board parts 41 on both ends that the tip sides warp toward the middle board part 41. Since the board parts 41 on both ends have resilience, if such a force is applied, the board parts 41 on both ends function to return back to their original states and exert a force to the inner circumferential surface of the pole member 22. This force can prevent the connecting member 4 inserted to the pole member 22 from falling off from the pole member 22.

Furthermore, a cut-out part 22b is formed at the opening end of the pole member 22 at a position opposing to the protrusion 44 when the board parts 41 of the connecting member 4 are inserted therein. Accordingly, in the case where, for example, the connecting member 4 is inserted from the opening end of the pole member 22 by mistake before it is attached to the stand base part 3, the protrusion (latch part) 44 of the connecting member 4 is engaged with the cut-out part 22b of the pole member 22 to stop inserting of the connecting member 4. This can prevent the connecting member 4 from thrusting into the pole member 22. Note that the structure of preventing the connecting member 4 from thrusting into the pole member 22 is not limited to the above.

When the connecting member 4 attached to the stand base part 3 is inserted from the opening end of the pole member 22, screw holes of the bosses 22a of the pole member 22 overlap with the through holes 33 opened at the stand base part 3. In such a state, after being inserted into the through holes 33, respectively, from the rear side of the stand base part 33, four setscrews (fixing member) 35 are screwed and fitted into the screw holes of the bosses 22a of the pole member 22, to fix the connection between the pole member 22 and the stand base part 3.

Next, the procedure of attaching the stand 1 having the structure described above to the main unit 10 is described. When the stand 1 is attached to the main unit 10, the main unit 10 is placed on a floor, a table or the like with the display panel 10a facing down. Furthermore, the attachment member 21 is attached to the rear surface of the main unit 10 with setscrews 23.

Meanwhile, two setscrews 34 are put into the through holes 32 to be screwed and fitted into the screw holes of the protrusions 43 while the protrusions 42, 43 of the connecting member 4 are fitted into the through holes 31, 32 formed at the recess 30a of the stand base part 3. This allows the connecting member 4 to be attached to the stand base part 3.

Subsequently, the board parts 41 of the connecting member 4 are inserted into the pole member 22 along the outer circumferential surfaces of the bosses 22a of the pole member 22, and the connecting member 4 is inserted into the pole member 22 until the opening end of the pole member 22 makes contact with the recess 30a of the stand base part 3. When the connecting member 4 is inserted into the pole member 22, the screw holes of the bosses 22a of the pole member 22 are continuous with the through holes 33 of the stand base part 3. Therefore, in this state, four setscrews 35 are put into the through holes 33 from the rear side of the stand base part 3, and screwed and fitted into the screw holes of the bosses 22a that are continuous to the through holes 33. This allows the connection between the pole member 22 (stand support part 2) and the stand base part 3 to be fixed. Thereafter, the main unit 10 is stood up and the television receiver is placed on a television table or the like while the main unit 10 is supported by the stand base part 3. It is noted that, when the television receiver is placed, the long side portion of the stand base part 3 where the recess 30a is located is arranged to be on the rear side of the television receiver.

At the stand 1 in Embodiment 1, the stand support part 2 and the stand base part 3 are connected by inserting the connecting member 4 into the pole member 2, and the connection is maintained by the connecting member 4. It is thus unnecessary for the user (operator) who rotates the setscrews 35 to hold the pole member 22 (stand support part 2) and the stand base part 3. Accordingly, the stand support part 2, stand base part 3 and the like may be prevented from falling and breaking during the screwing operation. Moreover, since the screw holes of the bosses 22a of the pole member 22 are continuous with the through holes 33 of the stand base part 3 when the connecting member 4 is inserted into the pole member 22, the screwing can be performed safely and easily, and also reliably even by one operator.

In the television receiver according to Embodiment 1, after the stand 1 is assembled, the connecting member 4 is inserted into the pole member 22 and arranged at a location not viewable from the outside, which avoids deterioration in designs of the stand 1 and the television receiver. Moreover, as the connecting member 4 serves as an important member in assembling the stand 1, the connecting member 4 may be configured with a distinguishable color such as white, red or the like. Such a configuration would not be a problem since the connecting member 4 is not viewed from the outside after assembling the stand 1.

It is necessary for the connecting member 4 to have such a strength that is able to maintain the connection between the pole member 22 and the stand base part 3 until the connection between the pole member 22 and the stand base part 3 is fixed with the setscrews 35. It is also necessary for the connecting member 4 to have resilience which is enough to prevent itself from easily falling off from the pole member 22 when inserted into the pole member 22. Thus, any material which can realize such strength and resilience may be used, and the number of board parts 41 constituting the connecting member 4 is not limited to three.

While the stand base part 3 and connecting member 4 are formed separately from each other in the stand 1 according to Embodiment 1 described above, they may be formed integrally. This eliminates the need for the work of attaching the connecting member 4 to the stand base part 3, more simplifying the work of attaching the stand 1 to the man unit 10. Moreover, in the case where the stand base part 3 is constituted by a stand base main unit and a cover which covers the upper side of the stand base main unit, the cover and the connecting member 4 may integrally be formed. Furthermore, in Embodiment 1, an example of a television receiver comprising a display device according to the present invention has been described. In addition thereto, the display device according to the present invention may also be applied to, for example, a digital photo frame that displays an image based on image data shot by an imaging device or image data received via a network on a display panel, or a digital signage that displays an image based on data pre-stored in an internal memory or data received via a network on a display panel.

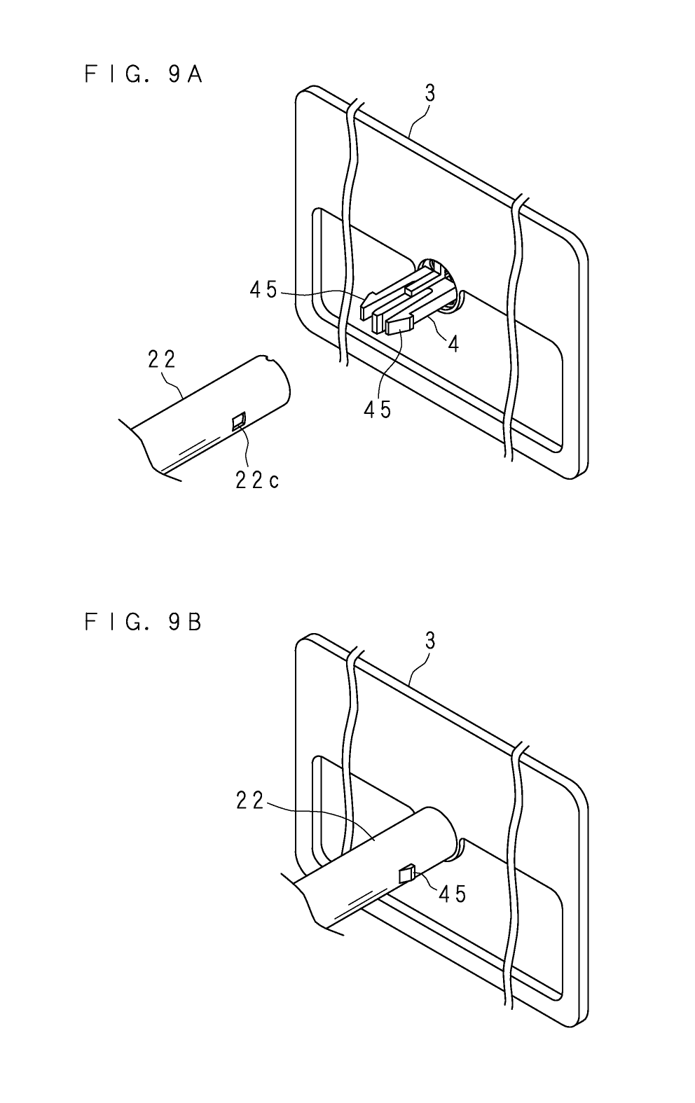

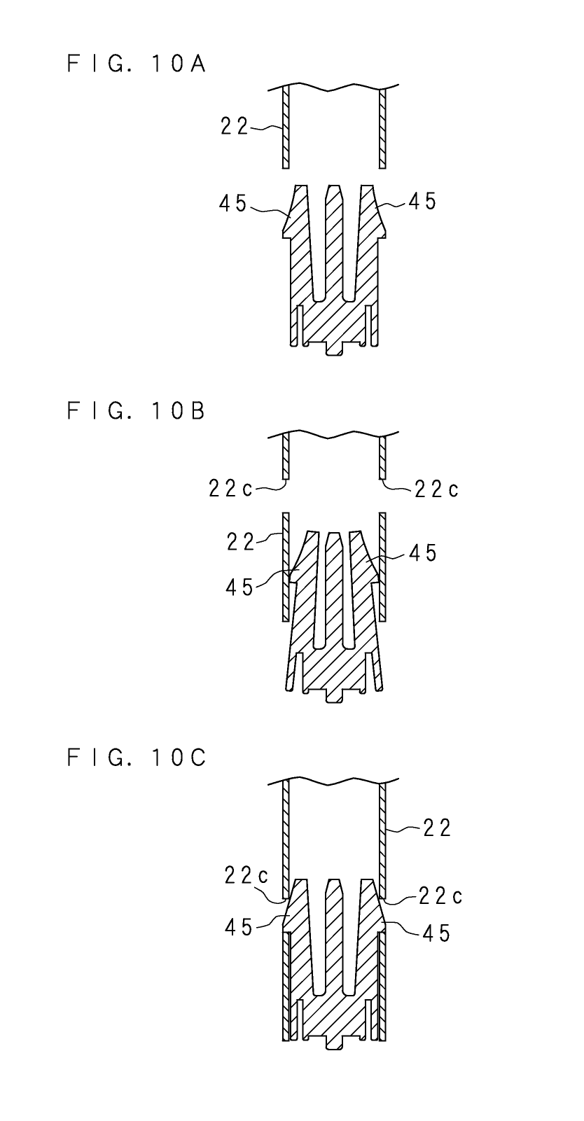

A modification of the stand 1 according to Embodiment 1 described above will now be described below. FIGS. 9A to 11 are schematic views illustrating the modification of the structure of the stand 1. FIGS. 10A to 10C show sectional views of the pole member 22 and connecting member 4 illustrated in FIGS. 9A and 9B, that are cut in a plane including an axis of the pole member 22 and extending in the longitudinal direction of the stand base part 3.

In the example illustrated in FIGS. 9A to 10C, in the pole member 22 according to Embodiment 1 described above, two through holes 22c having rectangular cross sections are opened near the positions where the protrusions 41a formed on the board parts 41 are located when the connecting member 4 is inserted. Moreover, in the examples illustrated in FIGS. 9A to 10C, at the protruding ends of the board parts 41 on both ends of the connecting member 4, claws 45 which are fitted into the through holes 22c and latched thereat when inserted into the pole member 22 are formed instead of the protrusions 41a.

According to such a structure, the claws 45 of the connecting member 4 are latched at the through holes 22c of the pole member 22 when the connecting member 4 is inserted into the pole member 22, as illustrated in FIGS. 10A to 10C, which can reliably prevents the connecting member 4 from easily falling off from the pole member 22. It is noted that the other configuration parts are similar to those in Embodiment 1 described above, and thus the description thereof will not be repeated.

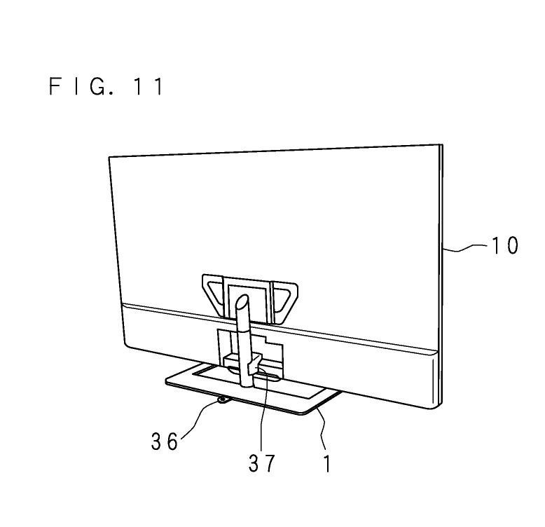

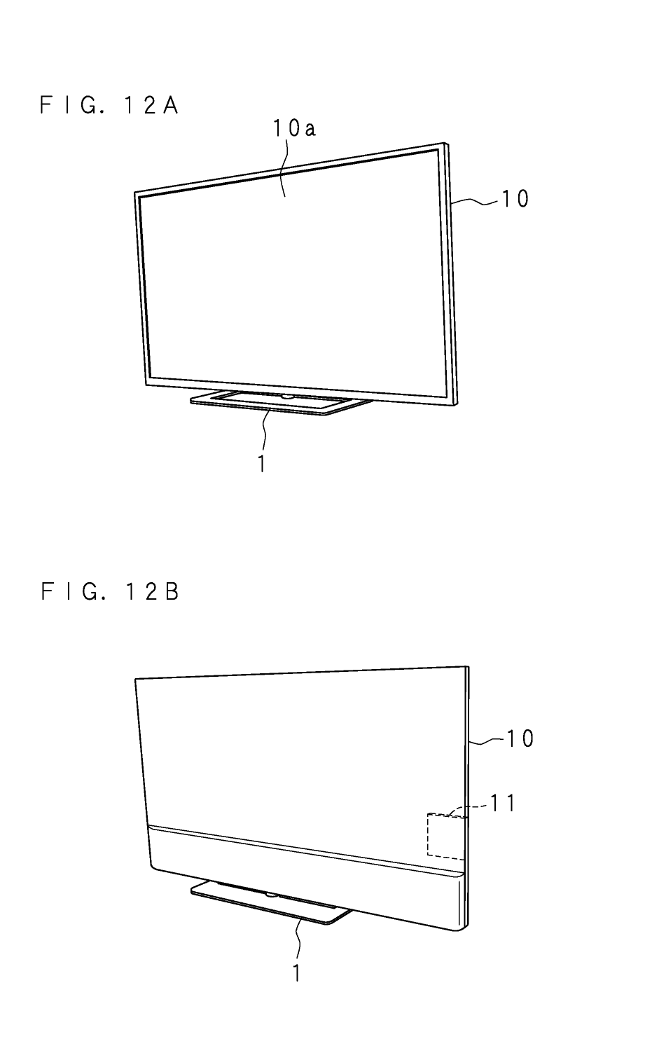

The structure illustrated in FIG. 11 is the one with the stand 1 formed to have more strength. For example, the stand base part 3 may be provided with a protrusion 36 on the rear side of the main unit 10, which can further prevent the main unit 10 from falling toward the rear side. Moreover, by providing a fixing part 37 for fixing the pole member 22 of the stand support part 2 on the rear surface (rear cabinet) of the main unit 10, the force for which the pole member 22 of the stand support part 2 supports the main unit 10 can be reinforced.

Embodiment 1 described above illustrated the structure where the stand 1 is attached to the rear side of the main unit 10, the present invention is not limited to such a structure. For example, a structure in which the stand 1 is attached to the long side part on the lower side of the main unit 10 may also be employed.

### Embodiment 2

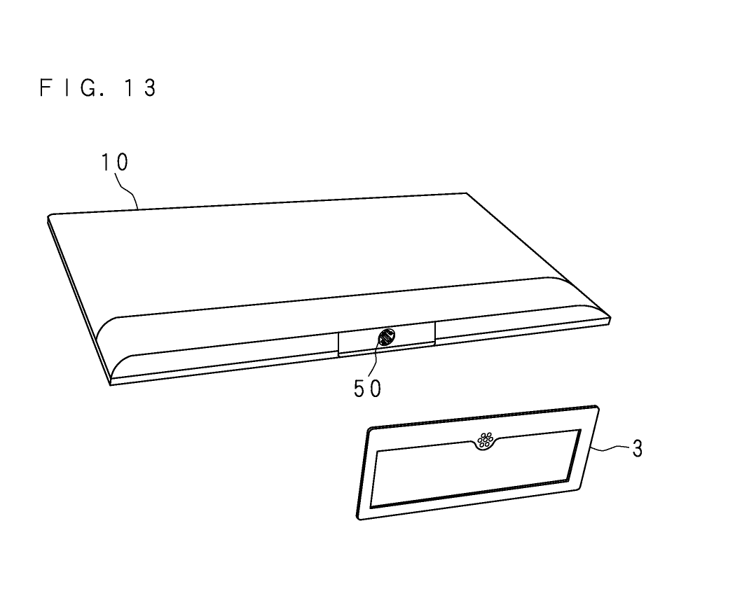

FIGS. 12A and 12B are perspective views of a television receiver according to Embodiment 2. FIG. 12A illustrates the state of the television receiver viewed from the display screen side, and FIG. 12B illustrates the state of the television receiver viewed from the rear side. The television receiver according to Embodiment 2 has a structure similar to the television receiver according to Embodiment 1 described above, and the similar configuration parts are denoted by the same reference numbers and will not be described in detail.

The television receiver according to Embodiment 2 comprises a main unit 10 and a stand (support part) 1 supporting the main unit 10, as in the television receiver according to Embodiment 1 described above. Moreover, the stand 1 supports the main unit 10 in the state where the display panel 10a is standing.

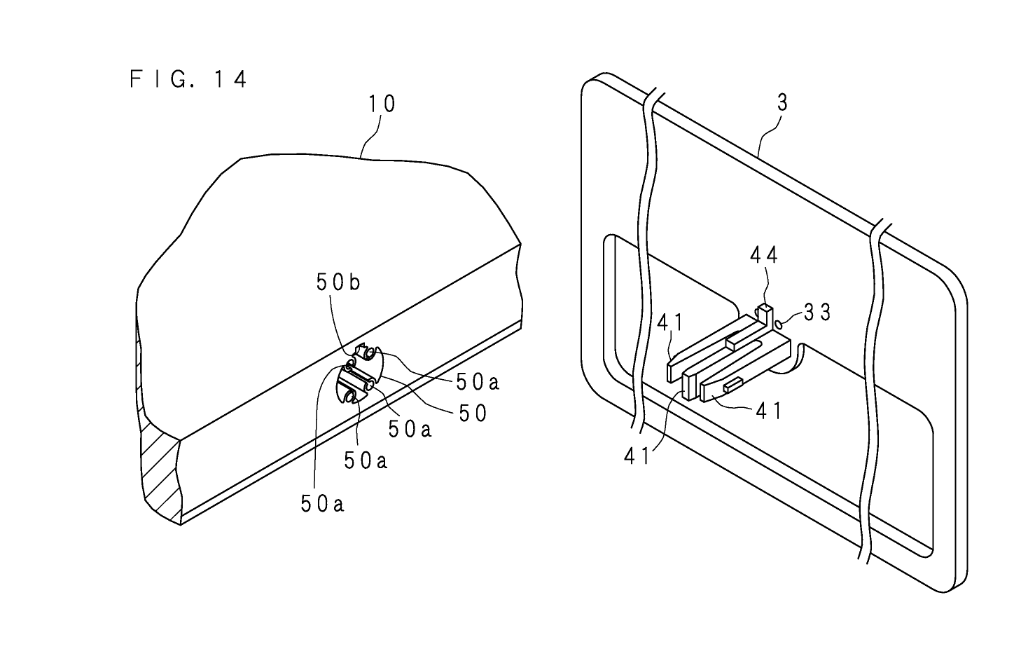

The structure and assembly procedure of the stand 1 according to Embodiment 2 will now be described below. FIGS. 13 and 14 are schematic views illustrating the structure of the main unit 10 and the stand 1 according to Embodiment 2. The television receiver according to Embodiment 2 is provided with a recess 50 at the middle of the lower end surface of the main unit 10 in place of the stand support part 2 in the television receiver according to Embodiment 1 described above. The recess 50 is formed to have a shape with a circular cross section having an axial direction being the vertical direction (short direction of the main unit 10). In other words, the recess 50 is formed such that the axis of its circular cross section is parallel to the display surface of the display panel 10a.

In the stand 1 according to Embodiment 2, one end of the connecting member 4 is attached to the stand base part 3 while the other end thereof is inserted into the recess 50 of the main unit 10, thereby connecting the main unit 10 and the stand base part 3 together. The stand base part 3 supports the main unit 10 through the connecting member 4.

Four bosses 50a are so provided as to bulge inward at four positions on the inner circumferential surface of the recess 50 at the opening end of the recess 50, as provided at the opening end of the pole member 22 into which the connecting member 4 is inserted in the stand support part 2 according to Embodiment 1 described above. Moreover, at the bosses 50a, screw holes are formed, respectively, extending in the axial direction of the circular cross section of the recess 50 (vertical direction of the main unit 10).

The bosses 50a are formed to have an outer diameter which allows the board parts 41 of the connecting member 4 to be inserted only at a unique position in the rotation direction centered on the axis of the circular cross section of the recess 50 when the board parts 41 are inserted from the opening end of the recess 50, and also allows to hold the inserted board parts 41 between their outer circumferential surfaces. Such a structure allows the bosses 50a to function as a guide part for guiding the inserting of the board parts 41 such that the connecting member 4 is (board parts 41 are) inserted at a unique position in the rotation direction centered on the axis of the circular cross section of the recess 50. Accordingly, the board parts 41 of the connecting member 4 are inserted into the recess 50 along the outer circumferential surfaces of the bosses 50a, thereby preventing the connecting member 4 from being inserted at an incorrect position with respect to the recess 50 (main unit 10).

Furthermore, at the opening end of the recess 50, a cut-out part 50b is formed at a position opposing to the protrusion 44 when the board parts 41 of the connecting member 4 are inserted therein. Therefore, for example, even when the connecting member 4 is inserted into the recess 50 of the main unit 10 by mistake before being attached to the stand base part 3, the protrusion 44 of the connecting member 4 is latched to the cut-out part 50b of the recess 50 to stop the inserting of the connecting member 4. This can prevent the connecting member 4 from being thrust into the recess 50. The structure that can prevent the connecting member 4 from being thrust into the recess 50 is not limited to the one described above.

When the connecting member 4 attached to the stand base part 3 is inserted into the recess 50 of the main unit 10, the screw holes of the bosses 50a of the recess 50 overlaps with the through holes 33 opened at the stand base part 3. In such a state, the four setscrews 35 (see FIG. 8) are put into the through holes 33 respectively from the rear side of the stand base part 3, and thereafter are screwed and fitted into the screw holes of the bosses 50a of the recess 50, so that the connection between the main unit 10 and the stand base part 3 are fixed.

In Embodiment 2, the structures of the stand base part 3 and the connecting member 4 are similar to those in Embodiment 1 described above. It is noted that, in Embodiment 1, the recess 30a is formed at the projection part 30 of the stand base part 3, and the through holes 31, 32, 33 are opened at the recess 30a. On the other hand, the stand base part 3 according to Embodiment 2 is not provided with the recess 30a at the projection part 30, as illustrated in FIG. 14, but only with through holes 31, 32, 33. It is noted that Embodiment 2 may also have a structure provided with the recess 30a at the projection part 30 and with the through holes 31, 32, 33 at the recess 30a as in Embodiment 1 described above.

Next, a procedure of attaching the stand 1 to the main unit 10 in the television receiver according to Embodiment 2 will be described. When the stand 1 is attached to the main unit 10, the main unit 10 is placed on a floor, table or the like with the display panel 10a facing down. Then, with a procedure similar to Embodiment 1 described above, the connecting member 4 is attached to the stand base part 3.

Subsequently, the board parts 41 of the connecting member 4 are inserted into the recess 50 along the outer circumferential surfaces of the bosses 50a of the recess 50 formed at the main unit 10, and the connecting member 4 is inserted into the recess 50 until the opening end of the recess 50 (lower end surface of the main unit 10) makes contact with the stand base part 3. When the connecting member 4 is inserted into the recess 50, the screw holes of the bosses 50a will be continuous to the through holes 33 of the stand base part 3. Therefore, in this state, the four setscrews 35 are put into the through holes 33 from the rear side of the stand base part 3, and are screwed and fitted into the screw holes of the bosses 50a that are continuous to the through holes 33. This allows the connection between the main unit 10 and the stand base part 3 to be fixed. Thereafter, the main unit 10 is stood up, and the television receiver is placed on a television table while the main unit 10 is supported at the stand base part 3.

Also in the television receiver according to Embodiment 2, an effect similar to that of the television receiver according to Embodiment 1 described above can be attained.

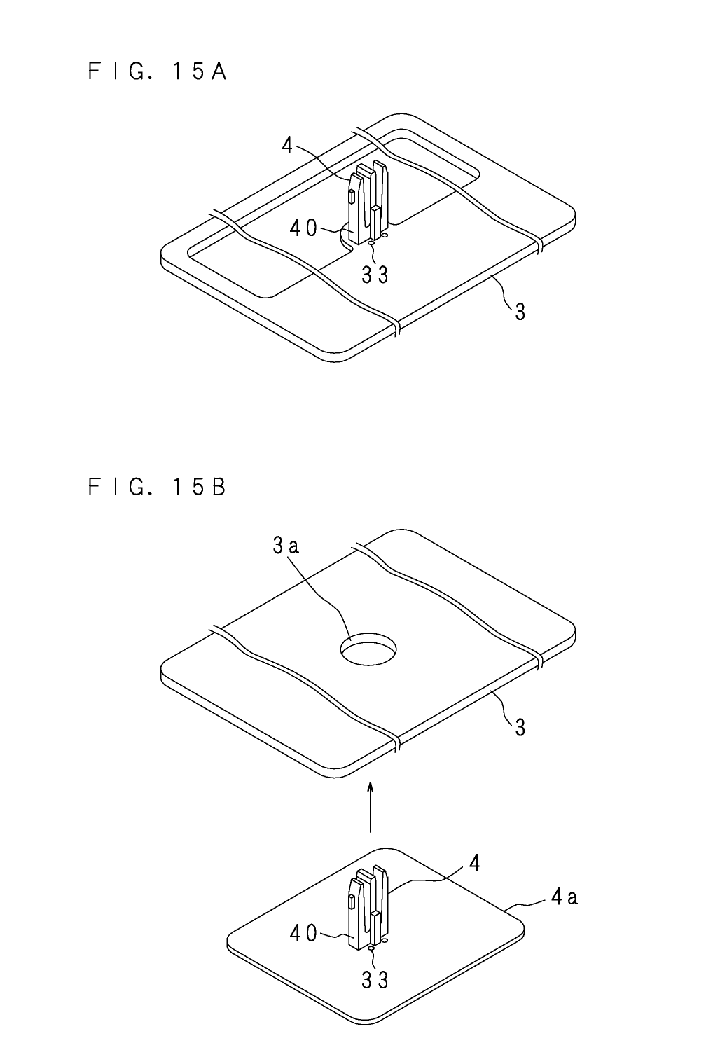

A modification of the stand base part 3 and the connecting member 4 according to Embodiments 1 and 2 above will now be described below. FIGS. 15A and 15B are schematic views illustrating the modification of the structure of the stand base part 3 and the connecting member 4.

While the stand base part 3 and the connecting member 4 are formed separately in the stand 1 according to Embodiments 1 and 2 as described above, they may also be formed integrally. FIG. 15A illustrates an example where the stand base part 3 and the connecting member 4 are formed integrally. Such a structure eliminates the need for the work of attaching the connecting member 4 to the stand base part 3 using the setscrews 34, which further simplifies the work of attaching the stand 1 (stand base part 3) to the main unit 10. It is noted that, when the stand base part 3 is formed integrally with the connecting member 4, the connecting member 4 will not be thrust into the pole member 22 or the recess 50 of the main unit 10 by mistake. Accordingly, as illustrated in FIG. 15A, it is unnecessary to form the protrusion 44 extending from the base 40 of the connecting member 4.

In the example illustrated in FIG. 15B, the stand base part 3 is formed to have a shape of a rectangular plate with a through hole 3a opened in the middle thereof. The stand base part 3 illustrated in FIG. 15B is formed to have a shape having a vertical dimension and a horizontal dimension substantially similar to those of the stand base part 3 of Embodiments 1 and 2, while the through hole 3a is opened at the same position as the projection part 30 in the stand base part 3 of Embodiments 1 and 2 described above. The connecting member 4 illustrated in FIG. 15B is formed to have a shape similar to the connecting member 4 in Embodiments 1 and 2 described above, except that the protrusions 42, 43 are not formed at the end surface of the base 40, the end surface of the base 40 being attached to the middle of a rectangular plate 4a. The rectangular plate 4a is formed to have a shape smaller than the stand base part 3, and four through holes 33 are opened at positions respectively corresponding to the screw holes of the bosses 22a of the pole member 22 (bosses 50a of the recess 50 of the main unit 10). In the case where the connecting member 4 is inserted into the through hole 3a from the rear surface (lower surface) side of the stand base part 3, as indicated by the arrow in FIG. 15B, the stand base part 3 serves as a cover which covers the rectangular plate 4a.

It may also be so configured that a recess having a substantially the same size as the rectangular plate 4a is formed on the rear surface (contact surface with the rectangular plate 4a) of the stand base part 3, and that the rectangular plate 4a is fitted into the recess when the connecting member 4 is inserted into the through hole 3a. In such a case, the connecting member 4 can be inserted into the through hole 3a at an appropriate position (orientation) with respect to the stand base part 3, and the rear surface of the stand base part 3 is in the same plane with the lower surface of the rectangular plate 4a when the connecting member 4 is inserted into the through hole 3a. Moreover, a locking part may also be provided that holds and locks the rear surface of the stand base part 3 and the upper surface (surface where the connecting member 4 is located) of the rectangular plate 4a with each other. Here, the locking part can function to fix the stand base part 3 and the rectangular plate 4a when the connecting member 4 is inserted into the through hole 3a. Also in the example illustrated in FIG. 15B, the connecting member 4 will not be thrust into the pole member 22 or the recess 50 of the main unit 10 by mistake, thereby eliminating the need for the protrusion 44 extending from the base 40 of the connecting member 4, as in the example illustrated in FIG. 15A.

In the example illustrated in FIG. 15B, the connecting member 4 (rectangular plate 4a) is attached to the stand base part 3 by inserting the connecting member 4 into the through hole 3a of the stand base part 3, thereby eliminating the need for the work of attaching the connecting member 4 to the stand base part 3 using the setscrews 34. In the case where the connecting member 4 attached to the stand base part 3 is inserted into the opening end of the pole member 22 (or the recess 50 of the main unit 10), the screw holes of the bosses 22a of the pole member 22 (or the bosses 50a at the recess 50 of the main unit 10) overlap with the through holes 33 opened at the rectangular plate 4a. In such a state, the four setscrews 35 are put into the through holes 33 respectively from the rear side of the rectangular plate 4a, and thereafter are screwed and fitted into the screw holes of the bosses 22a of the pole member 22 (or the bosses 50a of the recess 50 of the main unit 10), thereby fixing the connection between the pole member 22 (or main unit 10) and the stand base part 3. In the example illustrated in FIG. 15B, after the stand 1 is assembled, the connecting member 4 is inserted into the pole member 22 or the recess 50 of the main unit 10 while the rectangular plate 4a is covered by the stand base part 3, to be located in a place not viewable from the outside, so as to avoid deterioration in designs of the stand 1 and the television receiver.

The embodiments disclosed herein are to be considered as merely illustrative and not restrictive in all aspects. The scope of the invention is defined by the appended claims rather than by the description preceding them, and all changes that fall within metes and bounds of the claims, or equivalence of such metes and bounds thereof are therefore intended to be embraced by the claims.

### EXPLANATION OF CODES

1 stand (support part)
2 stand support part
3 stand base part (support member)
4 connecting member
10 main unit
10a display panel
22 pole member
22a boss (guide part)
22b cut-out part
31, 32 through hole
35 setscrew (fixing member)
40 base
41 board part
41a protrusion
42, 43 protrusion
44 protrusion (latch part)
50 recess

What is claimed is:

1-11. (canceled)

12. A display device comprising:
a main unit provided with a display panel; and
a support part supporting the main unit in a state where the display panel is standing, wherein
the support part comprises:
a tubular pole member so attached to the main unit as to have an axis being parallel to a display surface of the display panel;
a support member supporting the main unit through the pole member;
a connecting member having one end attached to the support member and another end inserted into an opening end of the pole member, to connect the pole member and the support member; and
a fixing member fixing the connection between the pole member and the support member through the connecting member.

13. The display device according to claim 12, wherein said another end of the connecting member has resilience to spread in a diameter direction of the pole member when inserted into the opening end of the pole member.

14. The display device according to claim 13, wherein
the connecting member has a base of a rectangular parallelepiped shape and a plurality of board parts extending from the base in a same direction with predetermined intervals, and
the board parts on both ends have protrusions at outer surfaces, a distance between respective protruding ends of the protrusions being longer than an inner diameter of the pole member.

15. The display device according to claim 14, wherein the board parts on the both ends have extending ends having outer surfaces being formed as tapered surfaces.

16. The display device according to claim 12, wherein
the opening end of the pole member is provided with a guide part guiding said another end of the connecting member such that said another end is inserted at a predetermined position in a rotation direction centered on an axis of the pole member, and
said another end of the connecting member is inserted into the opening end of the pole member in accordance with the guide part.

17. The display device according to claim 16, wherein
the support member has a hole at an appropriate position, and
said one end of the connecting member has a protrusion to be fitted into the hole of the support member at a predetermined position in a rotation direction centered on the axis of the pole member into which said another end is inserted.

18. The display device according to claim 12, wherein, at least one of the connecting member and the pole member is so configured, when said another end of the connecting member is inserted into the opening end of the pole member, that the connecting member is not to be inserted further than a predetermined position in the axial direction of the pole member.

19. The display device according to claim 18, wherein
the opening end of the pole member is provided with a cut-out part at an appropriate position, and
said one end of the connecting member is provided with a latch part to be engaged with the cut-out part, when said another end is inserted into the opening end of the pole member, to stop inserting of the connecting member.

20. A display device comprising:
a main unit provided with a display panel; and
a support part supporting the main unit in a state where the display panel is standing, wherein
the main unit comprises a recess having a circular cross section with an axial direction being a vertical direction, and
the support part comprises:
a support member supporting the main unit;
a connecting member having one end attached to the support member and another end inserted into the recess of the main unit, to connect the main unit and the support member; and
a fixing member fixing the connection between the main unit and the support member through the connecting member.

21. The display device according to claim 12, wherein the support member and the connecting member are integrally molded.

22. The display device according to claim 12, wherein the connecting member is inserted into an inside of the pole member.

23. A television receiver comprising:
the display device according to claim 12; and
a reception unit receiving a television broadcast, wherein
the television receiver displays an image on the display device based on the television broadcast received by the reception unit.
